(19) United States
(12) Patent Application Publication
(10) Pub. No.: US 2024/0030038 A1
(43) Pub. Date: Jan. 25, 2024

(54) ATOMIC LAYER ETCHING (ALE) APPARATUS AND ALE METHOD BASED ON THE APPARATUS

(71) Applicant: Samsung Electronics Co., Ltd., Suwon-si (KR)

(72) Inventors: Seungmin Shin, Suwon-si (KR); Joonyoung Kim, Suwon-si (KR); Kijong Park, Suwon-si (KR); Sunjoong Song, Suwon-si (KR); Seungcheol Chae, Suwon-si (KR)

(21) Appl. No.: 18/139,840

(22) Filed: Apr. 26, 2023

(30) Foreign Application Priority Data
Jul. 20, 2022 (KR) 10-2022-0089884

(51) Int. Cl. H01L 21/311; H01L 21/67; H01L 21/687

(52) U.S. Cl. CPC H01L 21/31122; H01L 21/67069; H01L 21/6875; H01L 21/68785

(57) ABSTRACT

Provided is an atomic layer etching (ALE) method including operation (a) of loading a substrate having a first surface and a second surface facing each other onto a chuck, operation (b) of cooling the substrate to a first temperature through a cooling fluid, operation (c) of forming a modified layer on the substrate through a reaction between a first source gas and the first surface of the substrate by spraying the first source gas toward the substrate from a shower head positioned above the chuck, operation (d) of heating the substrate to a second temperature through a laser beam, and operation (e) of removing the modified layer of the substrate through a reaction between a second source gas and the modified layer of the substrate by spraying the second source gas from the shower head toward the first surface of the substrate.

### CROSS-REFERENCE TO RELATED APPLICATION

This application is based on and claims priority under 35 U.S.C. §119 to Korean Patent Application No. 10-2022-0089884, filed on Jul. 20, 2022, in the Korean Intellectual Property Office, the disclosure of which is incorporated by reference herein in its entirety.

### BACKGROUND

Aspects of the inventive concept relate to an atomic layer etching (ALE) apparatus and an ALE method, and more particularly, to an ALE apparatus and an ALE method capable of performing an ALE process at different temperatures according to stages.

As the geometries of structures on a semiconductor substrate continue to shrink and types of structures evolve, etching challenges are increasing. A technique used to solve this problem is ALE. Here, the ALE may typically refer to a technique for etching a material layer with atomic precision. For example, one or several monolayers may be removed at a time through the ALE. In general, an ALE process may be performed by chemically modifying a surface to be etched and then selectively removing a modified layer.

### SUMMARY

Aspects of the inventive concept provide an atomic layer etching (ALE) method capable of providing different temperatures according to process operations during an ALE process.

Aspects of the inventive concept also provide an ALE apparatus capable of forming a thick modified layer by maintaining a low temperature in an operation of modifying a surface during an ALE process.

In addition, the technical goals to be achieved by aspects of the inventive concept are not limited to the technical goals mentioned above, and other technical goals may be clearly understood by one of ordinary skill in the art from the following descriptions.

According to an aspect of the inventive concept, there is provided an atomic layer etching (ALE) method including operation (a) of loading a substrate having a first surface and a second surface facing each other onto a chuck, operation (b) of cooling the substrate to a first temperature through a cooling fluid, operation (c) of forming a modified layer on the substrate through a reaction between a first source gas and the first surface of the substrate by spraying the first source gas toward the substrate from a shower head positioned above the chuck, operation (d) of heating the substrate to a second temperature through a laser beam, and operation (e) of removing the modified layer of the substrate through a reaction between a second source gas and the modified layer of the substrate by spraying the second source gas from the shower head toward the first surface of the substrate.

According to another aspect of the inventive concept, there is provided an atomic layer etching (ALE) method including operation (a) of loading a substrate having a first surface and a second surface facing each other onto a chuck, operation (b) of forming a modified layer on the substrate through a reaction between a first source gas and the first surface by spraying the first source gas toward the substrate from a shower head positioned above the chuck while the substrate is being cooled to a first temperature through a cooling fluid, and operation (c) of removing the modified layer of the substrate through a reaction between a second source gas and the modified layer of the substrate by spraying the second source gas toward the modified layer of the substrate from the shower head while the substrate is being heated to a second temperature through a laser beam.

According to another aspect of the inventive concept, there is provided an atomic layer etching (ALE) apparatus including a process chamber, a chuck configured to support a substrate having a first surface and a second surface facing each other, a shower head positioned above the substrate, a first source gas supply configured to supply a first source gas to the shower head, a second source gas supply configured to supply a second source gas to the shower head, a laser beam supply configured to irradiate a laser beam onto the substrate, and a cooling fluid supply configured to supply a cooling fluid into the process chamber.

### BRIEF DESCRIPTION OF THE DRAWINGS

Embodiments of the inventive concept will be more clearly understood from the following detailed description taken in conjunction with the accompanying drawings in which:

FIG. 1 is a schematic cross-sectional view of an atomic layer etching (ALE) apparatus according to an embodiment;

FIG. 2 is a schematic cross-sectional view of an ALE apparatus according to an embodiment;

FIG. 3 is a flowchart of an ALE method according to an embodiment;

FIG. 4 is a flowchart of an ALE method according to an embodiment;

FIG. 5 is a schematic cross-sectional view of each operation of an ALE method according to an embodiment;

FIGS. 6A to 6E are cross-sectional views sequentially showing an ALE method according to an embodiment;

FIG. 7 is a cross-sectional view showing an ALE method according to an embodiment of the inventive concept;

FIGS. 8A to 8E are cross-sectional views sequentially showing an ALE method according to an embodiment;

FIG. 9 is a flowchart of an ALE method according to an embodiment;

FIG. 10 is a schematic cross-sectional view of each operation of an ALE method according to an embodiment;

FIGS. 11A to 11C are cross-sectional views sequentially showing an ALE method according to an embodiment; and

FIGS. 12A to 12C are cross-sectional views sequentially showing an ALE method according to an embodiment.

### DETAILED DESCRIPTION OF THE EMBODIMENTS

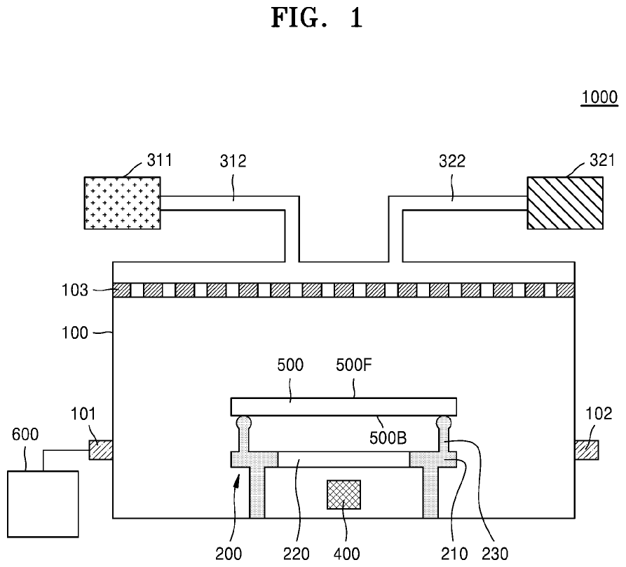

FIG. 1 is a schematic cross-sectional view of an atomic layer etching (ALE) apparatus 1000 according to an embodiment.

Referring to FIG. 1, the ALE apparatus 1000 may include a process chamber 100, a chuck 200, a first source gas supply 311, a second source gas supply 321, a laser beam supply 400, and a cooling fluid supply 600.

The process chamber 100 of the ALE apparatus 1000 may provide a processing space. The processing space of the process chamber 100 is provided as a space in which a substrate 500 is processed, and an entrance gate for entry and exit of the substrate 500 may be provided at one side of the process chamber 100. The processing space of the process chamber 100 may be provided as a space sealable from the space outside the process chamber 100. The process chamber 100 may have a cylindrical shape, an elliptic cylindrical shape, or a polygonal column-like shape.

An exhaust port may be formed at a lower portion of the process chamber 100 of the ALE apparatus 1000. An exhaust device is connected to the exhaust port of the process chamber 100 through a pipe and may be configured to exhaust materials in the process chamber 100 to the outside of the process chamber 100. The exhaust device may include a vacuum pump. The exhaust device may control the internal pressure of the processing space of the process chamber 100 by evacuating materials in the processing space of the process chamber 100 and may also exhaust reaction byproducts generated during processing of the substrate 500 out of the process chamber 100.

The process chamber 100 of the ALE apparatus 1000 may include a shower head 103 in an upper portion thereof. When viewed from above, the shower head 103 of the process chamber 100 may have a polygonal shape like a rectangular shape or a circular shape. The shower head 103 may include a plurality of holes penetrating through the shower head 103. The shower head 103 may evenly spray a first source gas and a second source gas into the processing space of the process chamber 100 through the holes thereof. According to some embodiments, the holes thereof may have a polygonal shape like a rectangular shape or a circular shape. According to some embodiments, the holes thereof may be configured to be symmetrical around the center point of the bottom surface of the shower head 103. Alternatively, more holes may be arranged in the central region of the bottom surface of the shower head 103 than in a peripheral region of the bottom surface of the shower head 103.

The process chamber 100 of the ALE apparatus 1000 may include a cooling fluid inlet 101 and a cooling fluid outlet 102 in sidewalls thereof. The cooling fluid inlet 101 and the cooling fluid outlet 102 may be positioned to face each other. The cooling fluid inlet 101 may be connected to the cooling fluid supply 600 and allow a cooling fluid to be introduced into the processing space of the process chamber 100 through the cooling fluid inlet 101 of the process chamber 100. The cooling fluid introduced through the cooling fluid inlet 101 may flow over a first surface 500F and a second surface 500B of the substrate 500 and may be discharged through the cooling fluid outlet 102. According to some embodiments, the cooling fluid may be low-temperature air or a gas containing helium (He). The cooling fluid introduced through the cooling fluid inlet 101 may rapidly lower the temperature of the substrate 500. The chemical reaction between the substrate 500 and the first source gas is highly reactive at a temperature of about 100° C. or less, and thus a modified layer may be easily formed on the substrate 500.

The chuck 200 of the ALE apparatus 1000 may include a circular ring 210 and a transparent window 220. The circular ring 210 of the chuck 200 may include a plurality of grips 230 protruding upward. According to some embodiments, the cross-section of a region in which the plurality of grips 230 of the chuck 200 support the substrate 500 may have a polygonal shape like a circular shape or a rectangular shape. According to some embodiments, the plurality of grips 230 of the circular ring 210 may be positioned symmetrically around the center of the top surface of the circular ring 210. The plurality of grips 230 may have the same height. The substrate 500 may be loaded on the plurality of grips 230 of the chuck 200. The substrate 500 may be supported by the plurality of grips 230 without being inclined to one side. The substrate 500 positioned on the plurality of grips 230 may be positioned to be spaced apart from the transparent window 220 by a certain distance. The cooling fluid may flow through the space between the substrate 500 and the transparent window 220.

The transparent window 220 of the chuck 200 may be located in the center hole of the circular ring 210. According to some embodiments, the material constituting the transparent window 220 may include quartz or a material having high light transmittance. According to some embodiments, the radius of the transparent window 220 may be from about 70% to about 90% of the outer radius of the circular ring 210. According to some embodiments, a wavelength at which the transparent window 220 is heated by a laser beam may be different from a wavelength at which the substrate 500 is heated by a laser beam. The transparent window 220 may prevent byproducts that may be generated during a substrate processing process from penetrating below the chuck 200.

The first source gas supply 311 of the ALE apparatus 1000 may be connected to a first source gas supply pipe 312. The first source gas supply pipe 312 may be connected to the upper portion of the process chamber 100. The first source gas supply 311 may supply a first source gas to the upper portion of the shower head 103 of the process chamber 100 through the first source gas supply pipe 312.

The first source gas may react with a target film of the substrate 500 to perform a fluorination process on the target film. A modified layer may be formed on the target film of the substrate 500 through the fluorination process. For example, the target film may include a metal-based dielectric film like an aluminum oxide (Al₂O₃) film, various metal oxide films, and metal-based metal nitride films or a high-k film.

Through the fluorination process for the target film, an upper portion of the target film may be converted into a modified layer. Thereafter, the remaining residual gas is purged with an inert gas like N₂ or Ar. After purging, the inert gas may be discharged to the outside of the process chamber 100 through a gas exhaust unit as exhaust gas. For reference, the inert gas may be referred to as a purge gas due to the purging action.

According to some embodiments, the first source gas may include hydrogen fluoride (HF), sulfur tetrafluoride (SF₄), and xenon tetrafluoride (XeF₄).

The second source gas supply 321 of the ALE apparatus 1000 may be connected to a second source gas supply pipe 322. The second source gas supply pipe 322 may be connected to the upper portion of the process chamber 100. The second source gas supply 321 may supply a second source gas to the upper portion of the shower head 103 of the process chamber 100 through the second source gas supply pipe 322.

The second source gas may react with the modified layer formed as the first source gas reacts with the target film of the substrate 500. The modified layer that reacted with the second source gas may be removed through ligand exchange. According to some embodiments, a portion of a metal oxide film like an Al₂O₃ film may be etched through a ligand exchange process. The thickness of a portion of the metal oxide film removed through the ligand exchange process may be several A or greater.

Thereafter, reaction by-products may be purged with an inert gas and discharged as exhaust gas, thereby completing one cycle of an ALE process. The cycle of the ALE process may be repeated several times until a metal oxide film or a metal nitride thin-film reaches a desired thickness.

According to some embodiments, the second source gas may include Trimethylaluminium (TMA), Sn(acac)₂, Al(CH₃)₃, Al(CH₃)₂Cl, SiCl₄, TiCl₄, BCl₃, and WF₆.

The laser beam supply 400 of the ALE apparatus 1000 may heat the substrate 500 by irradiating a laser beam to the substrate 500. The laser beam supply 400 may rapidly heat the substrate 500 by using a non-contact heater. According to some embodiments, the laser beam supply 400 may be located below the transparent window 220 of the chuck 200.

A laser beam generated by the laser beam supply 400 may be irradiated onto the entire or a part of the second surface 500B of the substrate 500. The laser beam may be a continuous wave having a wavelength from about 200 nm to about 1200 nm.

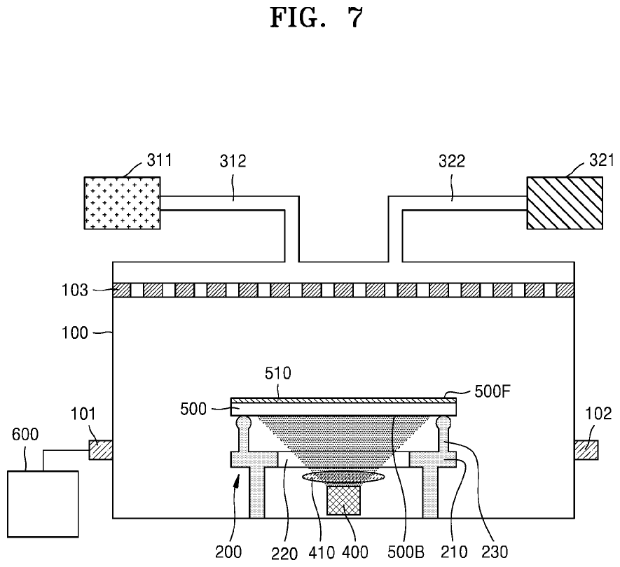

The laser beam supply 400 positioned under the transparent window 220 may irradiate a laser beam onto the second surface 500B of the substrate 500 through the transparent window 220. When a laser beam generated by the laser beam supply 400 passes through the transparent window 220, the laser beam may be refracted by the refractive index of the transparent window 220. According to some embodiments, a lens (410 of FIG. 7) may be positioned between the laser beam supply 400 and the transparent window 220. The lens (410 of FIG. 7) may be a convex lens or a concave lens. According to some embodiments, a laser beam that passed through the lens may be refracted to an edge of the substrate 500.

According to some embodiments, the laser beam supply 400 may be positioned above the substrate 500 to irradiate a laser beam onto the first surface 500F of the substrate 500. The laser beam supply 400 may irradiate a laser beam onto the entire or a part of the first surface 500F of the substrate 500.

A conventional ALE apparatus uses a contact heater to maintain a temperature (about 200° C.) that may be used for both a fluorination process and a ligand exchange process during an ALE process. A metaoxide film or a metal nitride film used in recent semiconductor devices has improved reactivity with a first source gas at a low temperature (about 100° C. or lower), thereby facilitating formation of a modified layer. Also, the modified layer has improved reactivity with a second source gas at a high temperature (about 300° C. or higher), thereby facilitating removal of the modified layer. Also, the ALE apparatus according to aspects of the inventive concept may perform a process of cooling a substrate by using a cooling fluid and perform a process of heating the substrate by using a laser beam supply, which is a non-contact heater. Through such a cooling process and a heating process, each operation of an ALE process may be performed at an optimal temperature. According to some embodiments, the thickness of a film that may be removed through one cycle may be dozens of A or greater.

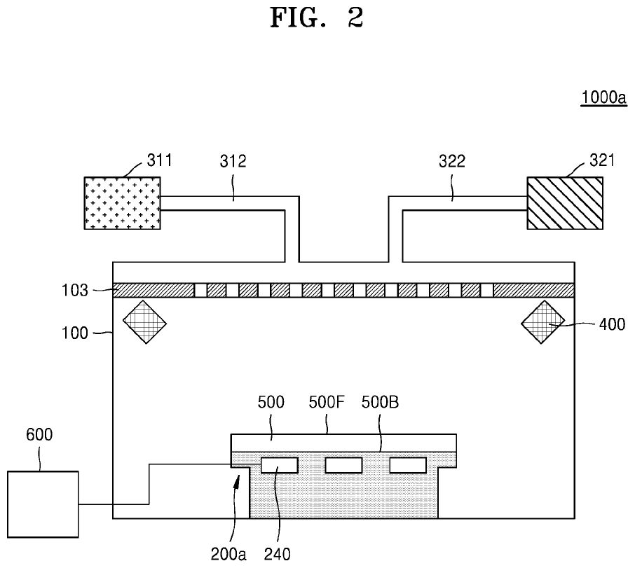

FIG. 2 is a schematic cross-sectional view of an ALE apparatus 1000a according to an embodiment.

Referring to FIG. 2, the ALE apparatus 1000a may include the process chamber 100, a chuck 200a, the first source gas supply 311, the second source gas supply 321, the laser beam supply 400, and the cooling fluid supply 600. Hereinafter, descriptions of the ALE apparatus 1000a of FIG. 2 that are identical to those of the ALE apparatus 1000 given above with reference to FIG. 1 will be omitted, and differences therebetween will be mainly described.

The chuck 200a of the ALE apparatus 1000a may be an electrostatic chuck. The electrostatic chuck may be configured to support the substrate 500 with an electrostatic force. According to some embodiments, the chuck 200a of the ALE apparatus 1000a may be a vacuum chuck. The vacuum chuck may be configured to selectively vacuum-adsorb the substrate 500. The second surface 500B of the substrate 500 loaded on the chuck 200a may entirely contact the chuck 200a. For example, the substrate 500 loaded on the chuck 200a may not be spaced apart from the chuck 200a.

The chuck 200a may include a cooling fluid flow pipe 240 therein. The cooling fluid flow pipe 240 may be connected to the cooling fluid supply 600. The cooling fluid supply 600 may supply a cooling fluid to the inside of the chuck 200a through the cooling fluid flow pipe 240. The cooling fluid flowing through the cooling fluid flow pipe 240 may rapidly cool the substrate 500.

The laser beam supply 400 of the ALE apparatus 1000a may be positioned over the substrate 500. The laser beam supply 400 may be configured to irradiate a laser beam onto the first surface 500F of the substrate 500. The laser beam supply 400 may be positioned to not to interfere with spraying paths of the first source gas and the second source gas. For example, the laser beam supply 400 may be positioned between the shower head 103 and the substrate 500. For example, the laser beam supply 400 may be positioned between the substrate 500 and a region of the shower head 103 without a through hole. According to some embodiments, the ALE apparatus 1000a may include a plurality of laser beam supplies 400 each supplying a laser beam. A laser beam supplied by the laser beam supply 400 may be a continuous wave having a wavelength from about 200 nm to about 1200 nm. Alternatively, a laser beam supplied by the laser beam supply 400 may be a pulse wave. The laser beam supply 400 may irradiate a laser beam having a wavelength absorbable by the substrate 500 to the first surface 500F of the substrate 500, thereby rapidly heating the substrate 500 in a non-contact manner.

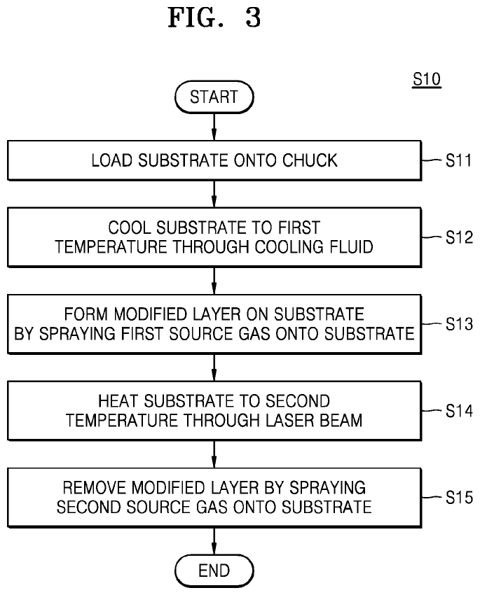

FIG. 3 is a flowchart of an ALE method according to an embodiment.

Referring to FIG. 3, in an ALE method S10, operation (a) of loading a substrate onto a chuck may be performed (operation S11). After operation (a), operation (b) of cooling the substrate to a first temperature through a cooling fluid may be performed (operation S12). After operation (b), operation (c) of forming a modified layer on the substrate by spraying a first source gas onto the substrate may be performed (operation S13). After operation (c), operation (d) of heating the substrate to a second temperature by irradiating a laser beam to the substrate may be performed (operation S14). After operation (d), operation (e) of removing the modified layer by spraying a second source gas onto the substrate may be performed (operation S15).

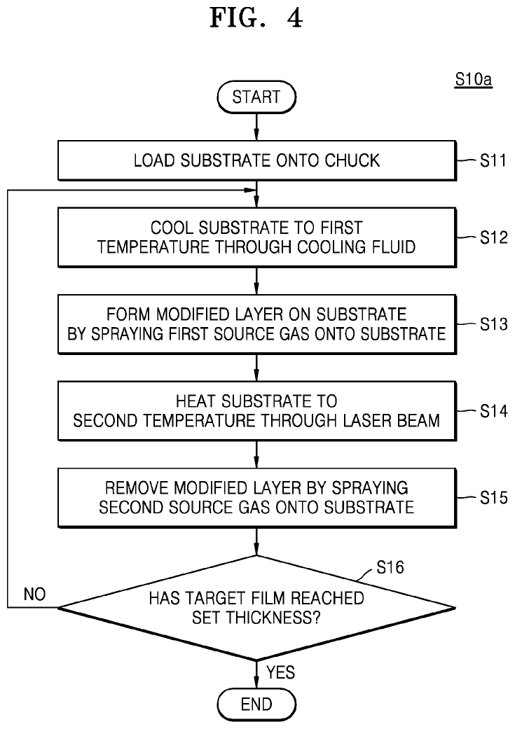

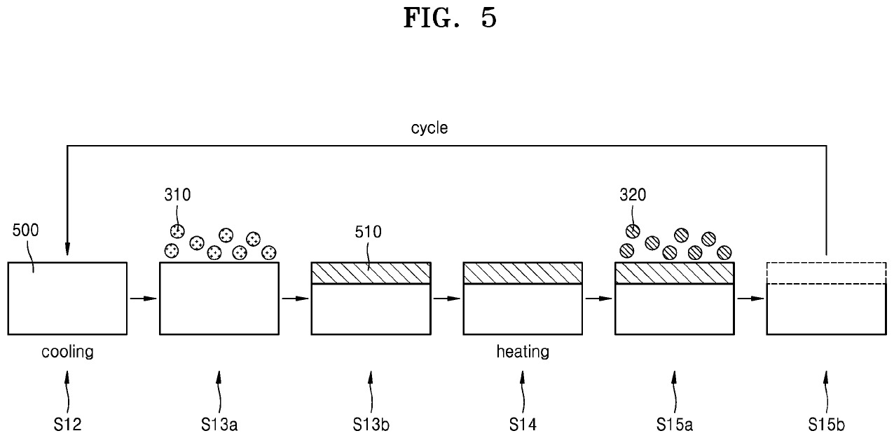

FIG. 4 is a flowchart of an ALE method 510a according to an embodiment. FIG. 5 is a schematic cross-sectional view of each operation of the ALE method 510a according to an embodiment. Hereinafter, descriptions of the ALE method 510a of FIG. 4 that are identical to those of the ALE method 510 given above with reference to FIG. 3 will be omitted, and differences therebetween will be mainly described.

Referring to FIG. 4, after operation (e) (operation S15), it may be determined whether a target film has reached a set thickness (operation S16). When the target film has reached the set thickness, the ALE process may be terminated. When the target film has not reached the set thickness, operations (b) to (e) may be repeated (operations S12-S15). While operations (b) to (e) are being repeated, the ALE method according to aspects of the inventive concept may rapidly change the temperature of the substrate to the first temperature or the second temperature in each operation. Each operation is performed at an optimized temperature, and thus, the number of repetitions needed until the target film reaches the set thickness may be reduced.

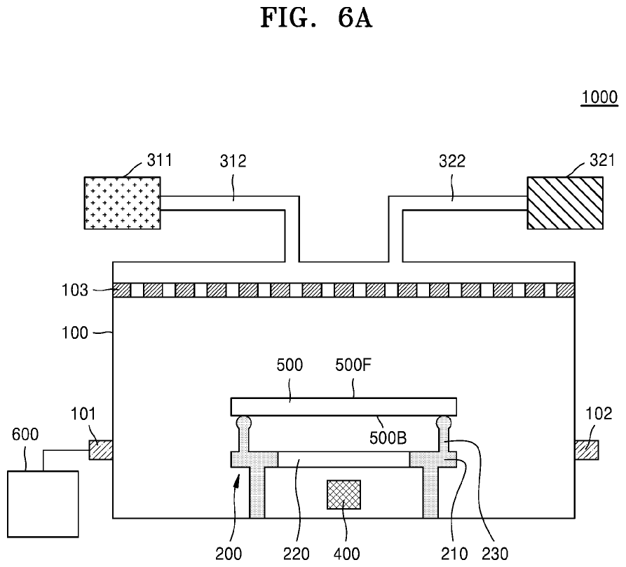

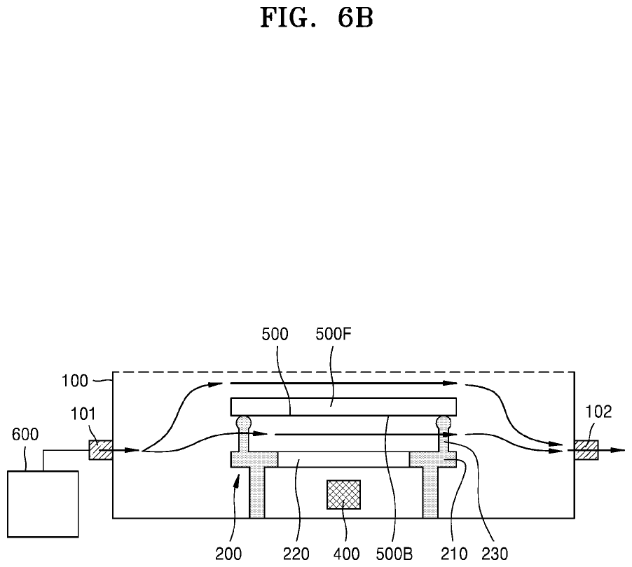

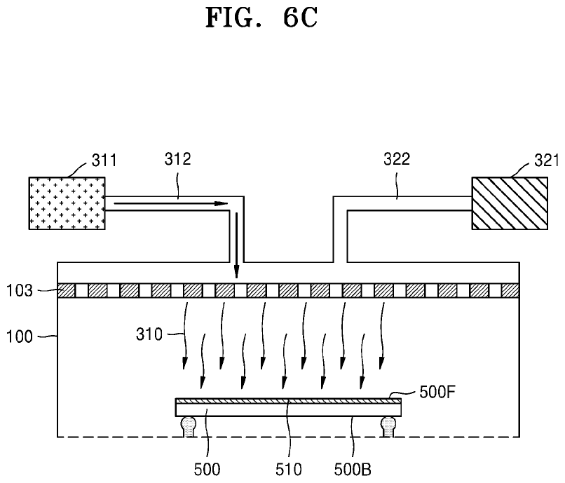

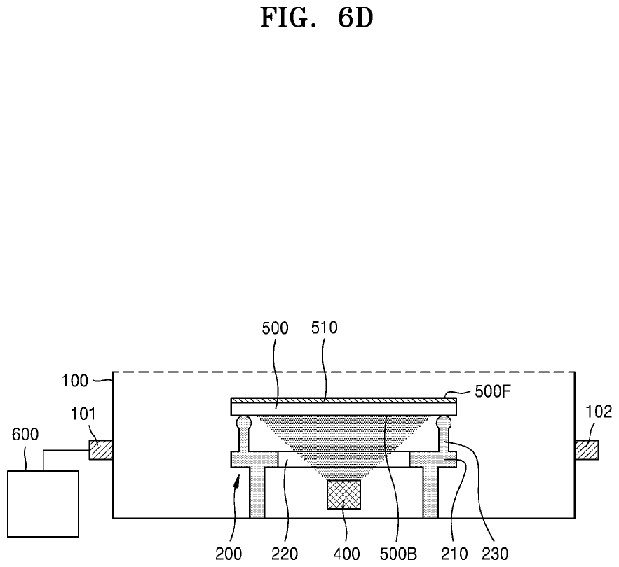

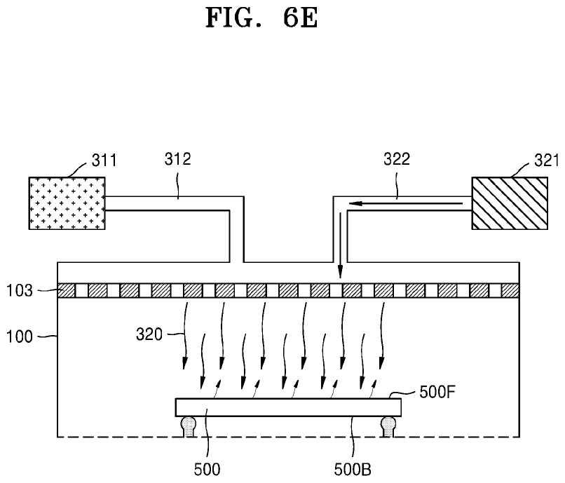

FIG. 5 shows the process sequence of the ALE method of FIG. 4 by focusing on changes of the substrate 500. The substrate 500 may be cooled to the first temperature through the cooling fluid (operation S12). A first source gas 310 may be sprayed onto the first surface of the substrate 500 at the first temperature (operation 513a). The first source gas 310 may react with the target film of the substrate 500 and form a modified layer 510 (operation 513b). The substrate 500 and the modified layer 510 may be heated to a second temperature through a laser beam supply (operation S14). A second source gas 320 may be sprayed onto the substrate 500 and the modified layer 510 at the second temperature (operation S15a). As the second source gas 320 and the modified layer 510 react with each other, the modified layer 510 may be evaporated and removed (operation S15b). The above-stated operations may be repeated until the target film of the substrate 500 reaches the set thickness. More detailed descriptions thereof will be given below with reference to FIGS. 6A to 6E.

FIGS. 6A to 6E are cross-sectional views sequentially showing an ALE method according to an embodiment.

FIG. 6A shows operation (a) (operation S11) in which a substrate is loaded onto a chuck.

Referring to FIG. 6A, the substrate 500 may include the first surface 500F and the second surface 500B that face each other. The first surface 500F of the substrate 500 may be a front-side surface of the substrate 500. The second surface 500B of the substrate 500 may be a backside surface of the substrate 500.

According to some embodiments, the chuck 200 may include the circular ring 210 and the transparent window 220. The circular ring 210 of the chuck 200 may include the plurality of grips 230 protruding upward. The substrate 500 may be loaded on the plurality of grips 230 of the chuck 200. The plurality of grips 230 may have the same height. The substrate 500 may be supported horizontally by the plurality of grips 230 without being inclined to one side. The substrate 500 positioned on the plurality of grips 230 may be positioned to be spaced apart from the transparent window 220 by a certain distance. The cooling fluid may flow through the space between the substrate 500 and the transparent window 220.

According to some embodiments, the transparent window 220 of the chuck 200 may be located in the center hole of the circular ring 210. The material constituting the transparent window 220 may include quartz or a material having high light transmittance.

FIG. 6B shows operation (b) (operation S12) of cooling the substrate 500 to a first temperature through the cooling fluid.

Referring to FIG. 6B, the cooling fluid supply 600 may be connected to the cooling fluid inlet 101 disposed on a side of the process chamber 100. The cooling fluid supply 600 may introduce the cooling fluid into the processing space in the process chamber 100 through the cooling fluid inlet 101. The cooling fluid introduced through the cooling fluid inlet 101 may flow over a first surface 500F and a second surface 500B of the substrate 500 and may be discharged to the outside through the cooling fluid outlet 102. The cooling fluid introduced through the cooling fluid inlet 101 may flow above and below the substrate 500 and may be discharged to the outside through the cooling fluid outlet 102.

When the temperature of the substrate 500 is about 100° C. or lower, the reaction between the first source gas and the target film of the substrate 500 becomes active, and thus a thicker modified layer may be formed. Operation (b) (operation S12) is a pre-processing operation for forming a thick modified layer and is an operation of cooling the substrate 500 to the first temperature. According to some embodiments, the first temperature may be from about 50° C. to about 90° C.

FIG. 6C shows operation (c) (operation S13) of forming the modified layer 510 by spraying the first source gas 310 from the shower head 103 toward the substrate 500.

Referring to FIG. 6C, the first source gas 310 sprayed from the shower head 103 may chemically react with the target film on the first surface 500F of the substrate 500. A region of the target film that has chemically reacted with the first source gas 310 may be referred to as the modified layer 510.

According to some embodiments, the first source gas 310 may include HF, SF₄, and XeF₄.

According to some embodiments, the target film may include a metal-based dielectric film like an Al₂O₃ film, various metal oxide films, and metal-based metal nitride films or a high-k film.

The shower head 103 may be located above the chuck 200. According to some embodiments, the shower head 103 may include through holes, and thus the first source gas 310 introduced to the upper portion of the shower head 103 may be evenly sprayed below the shower head 103.

The first source gas supply 311 may be connected to the first source gas supply pipe 312. The first source gas supply pipe 312 may be connected to the upper portion of the process chamber 100. The first source gas supply 311 may supply the first source gas 310 to the processing space inside the process chamber 100 through the first source gas supply pipe 312. The first source gas 310 supplied to the upper portion of the processing space may be sprayed onto the first surface 500F of the substrate 500 through the shower head 103.

The first source gas 310 uniformly sprayed onto the first surface 500F of the substrate 500 through the shower head 103 may react with the target film and evenly form the modified layer 510.

FIG. 6D shows operation (d) (operation S14) of heating a substrate to a second temperature by using a laser beam.

Referring to FIG. 6D, the laser beam supply 400 capable of supplying a laser beam may be located below the transparent window 220. A laser beam supplied by the laser beam supply 400 may pass through the transparent window 220 and be irradiated onto the second surface 500B of the substrate 500. The laser beam may be refracted by the refractive index of the transparent window 220 while passing through the transparent window 220. The laser beam may be irradiated onto the entire or a part of the second surface 500B of the substrate 500. The laser beam may be a continuous wave having a wavelength absorbable by the substrate 500. According to some embodiments, the laser beam may be a continuous wave having a wavelength from about 200 nm to about 1200 nm. Alternatively, the laser beam may be a pulse wave.

When the second source gas and the modified layer 510 chemically react with one another, the higher the temperature is, the higher the reactivity may be. When the modified layer 510 that reacted with the second source gas is evaporated and removed at a high temperature (about 400° C. or higher), the reactivity is good, and thus, the process speed may be fast. Operation (d) (operation S14) is a pre-processing process for the efficient removal of the modified layer 510, and the substrate 500 and the modified layer 510 may be heated to the second temperature. The second temperature may be from about 250° C. to about 400° C.

In general, the process of removing the modified layer 510 is performed at the same temperature as the process of forming the modified layer 510 on the substrate 500, and thus, there is a limit in increasing the temperature. For example, when the substrate is heating to a second temperature of about 250° C., the process of removing the modified layer 510 is performed at about 250° C. The laser beam supply 400 according to aspects of the inventive concept is a non-contact heater and may facilitate rapid change of the temperature of the substrate 500. For example, by appropriately setting the temperature in an operation of removing the modified layer 510, the modified layer 510 may be removed efficiently.

FIG. 6E shows operation (e) (operation S15) of removing the modified layer 510 by spraying the second source gas 320 from the shower head 103 toward the substrate 500. Referring to FIG. 6E, the second source gas 320 sprayed from the shower head 103 may chemically react with the modified layer 510 on the first surface 500F of the substrate 500. The modified layer 510 that reacted with the second source gas 320 may be evaporated and removed from the substrate 500.

According to some embodiments, the second source gas 320 may include TMA, Sn(acac)₂, Al(CH₃)₃, Al(CH₃)₂Cl, SiCl₄, TiCl₄, BCl₃, and WF₆. Here, in Sn(acac)₂, acac may refer to CH₃COCH₂COCH₃.

The shower head 103 may be located above the chuck 200. According to some embodiments, the shower head 103 may include through holes, and thus, the second source gas 320 introduced to the upper portion of the shower head 103 may be evenly sprayed below the shower head 103.

The second source gas supply 321 may be connected to the second source gas supply pipe 322. The second source gas supply pipe 322 may be connected to the upper portion of the process chamber 100. The second source gas supply 321 may supply the second source gas 320 to the processing space in the process chamber 100 through the second source gas supply pipe 322. The second source gas 320 supplied to the upper portion of the processing space may be sprayed onto the first surface 500F of the substrate 500 through the shower head 103.

The second source gas 320 uniformly sprayed onto the first surface 500F of the substrate 500 through the shower head 103 may react with the modified layer 510 and evenly remove the modified layer 510.

FIG. 7 is a cross-sectional view showing an ALE method according to an embodiment of the inventive concept. In detail, FIG. 7 is a cross-sectional view showing an operation (operation S14) of heating a substrate to a second temperature in the ALE process (S10 of FIG. 3) described above. Hereinafter, in the ALE method of FIG. 7, descriptions of operations (a), (b), (c), and (e) that are identical to those in the ALE method described with reference to FIGS. 6A to 6E will be omitted, and operation (d) (operation S14) with a difference will be described.

Referring to FIG. 7, the laser beam supply 400 capable of supplying a laser beam may be located below the transparent window 220. A laser beam supplied by the laser beam supply 400 may pass through the transparent window 220 and be irradiated onto the second surface 500B of the substrate 500. The laser beam may be refracted by the refractive index of the transparent window 220 while passing through the transparent window 220.

A lens 410 may be positioned between the laser beam supply 400 and the transparent window 220. According to some embodiments, the lens 410 may be a convex lens or a concave lens. When the lens 410 is a convex lens, the lens 410 may collect a laser beam and locally irradiate the laser beam onto a certain region of the substrate 500. When the lens 410 is a concave lens, the lens 410 may spread a laser beam and irradiate the laser beam onto the entire region of the substrate 500. According to some embodiments, a laser beam may be refracted by the refractive index of the lens 410 while passing through the lens 410. A laser beam passed through the lens 410 may be refracted again while passing through the transparent window 220. A laser beam that passed through the lens 410 and the transparent window 220 may be irradiated onto the entire or a part of the second surface 500B of the substrate 500.

The lens 410 may expand the irradiation range of a laser beam when a distance between the laser beam supply 400 and the substrate 500 is too close to sufficiently irradiate the laser beam onto the substrate 500. The refractive index of the lens 410 may be appropriately changed according to the distance between the laser beam supply 400 and the substrate 500.

The laser beam may be a continuous wave having a wavelength absorbable by the substrate 500. For example, the laser beam may be a continuous wave having a wavelength from about 200 nm to about 1200 nm. Alternatively, the laser beam may be a pulse wave.

The laser beam supply 400 is a non-contact heater and may facilitate rapid change of the temperature of the substrate 500. For example, by appropriately setting the temperature in an operation of removing the modified layer 510, the modified layer 510 may be removed efficiently.

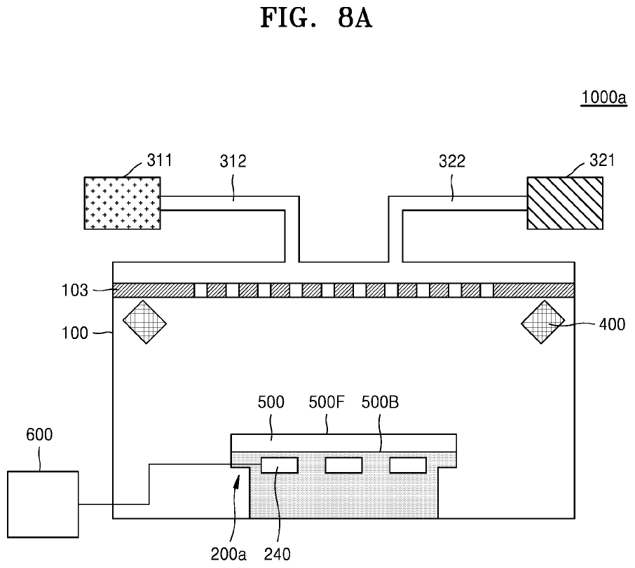

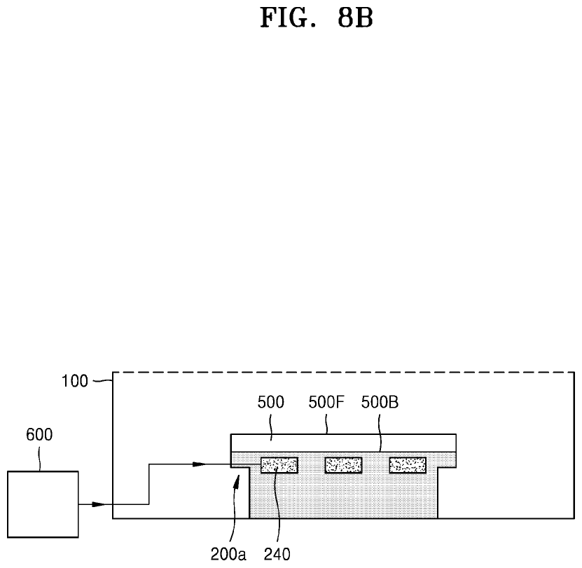

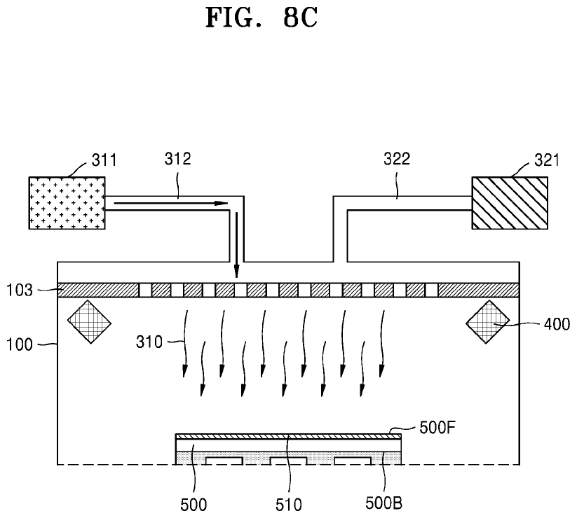

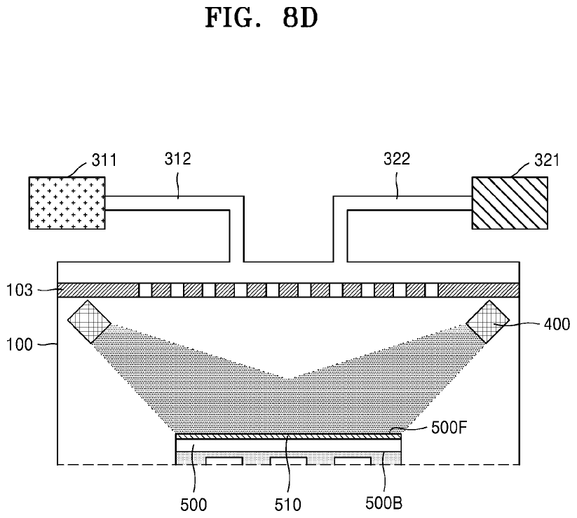

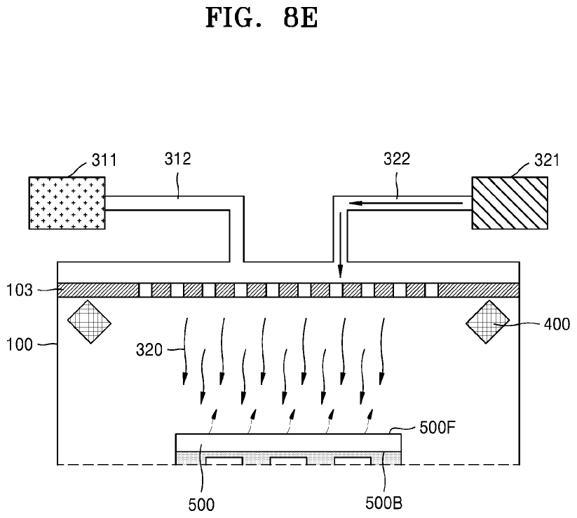

FIGS. 8A to 8E are cross-sectional views sequentially showing an ALE method according to an embodiment. Hereinafter, descriptions of the ALE method of FIGS. 8A to 8E that are identical to those of the ALE method given above with reference to FIGS. 6A to 6E will be omitted, and differences therebetween will be mainly described.

FIG. 8A shows operation (a) (operation S11) in which a substrate is loaded onto a chuck. Referring to FIG. 8A, the substrate 500 may include the first surface 500F and the second surface 500B that face each other. The first surface 500F of the substrate 500 may be a front-side surface of the substrate 500. The second surface 500B of the substrate 500 may be a backside surface of the substrate 500.

According to some embodiments, the chuck 200a of the ALE apparatus 1000a may be an electrostatic chuck. The electrostatic chuck may be configured to support the substrate 500 with an electrostatic force. According to some embodiments, the chuck 200a of the ALE apparatus 1000a may be a vacuum chuck. The vacuum chuck may be configured to selectively vacuum-adsorb the substrate 500. The second surface 500B of the substrate 500 loaded on the chuck 200a may entirely contact the chuck 200a. For example, the substrate 500 loaded on the chuck 200a may not be spaced apart from the chuck 200a.

FIG. 8B shows operation (b) (operation S12) of cooling the substrate 500 to a first temperature through the cooling fluid.

Referring to FIG. 8B, the chuck 200a may include the cooling fluid flow pipe 240 therein. The cooling fluid supply 600 may be connected to the cooling fluid flow pipe 240 inside the chuck 200a. The cooling fluid supply 600 may supply a cooling fluid to the inside of the chuck 200a through the cooling fluid flow pipe 240. The cooling fluid supplied into the chuck 200a may cool the substrate 500 loaded on the chuck 200a to the first temperature.

When the temperature of the substrate 500 is about 100° C. or lower, the reaction between the first source gas and the target film of the substrate 500 becomes active, and thus a thicker modified layer may be formed. Operation (b) (operation S12) is a pre-processing operation for forming a thick modified layer and is an operation of cooling the substrate 500 to the first temperature. According to some embodiments, the first temperature may be from about 50° C. to about 90° C.

FIG. 8C shows operation (c) (operation S13) of forming the modified layer 510 by spraying the first source gas 310 from the shower head 103 toward the substrate 500.

Referring to FIG. 8C, the first source gas 310 sprayed from the shower head 103 may chemically react with the target film on the first surface 500F of the substrate 500. A region of the target film that has chemically reacted with the first source gas 310 may be referred to as the modified layer 510.

FIG. 8D shows operation (d) (operation S14) of heating a substrate to a second temperature by using a laser beam.

Referring to FIG. 8D, the laser beam supply 400 for supplying a laser beam may be located above the substrate 500. The laser beam supply 400 may be configured to irradiate a laser beam onto the first surface 500F of the substrate 500. According to some embodiments, the laser beam supply 400 may be positioned to not to interfere with spraying paths of the first source gas and the second source gas. For example, the laser beam supply 400 may be positioned between the shower head 103 and the substrate 500. For example, the laser beam supply 400 may be positioned between the substrate 500 and a region of the shower head 103 without a through hole. According to some embodiments, the ALE apparatus 1000a may include a plurality of laser beam supplies 400 each supplying a laser beam.

A laser beam supplied from each laser beam supply 400 may irradiate the entire or a part of the first surface 500F of the substrate 500. The laser beam may be a continuous wave having a wavelength absorbable by the substrate 500. For example, the laser beam may be a continuous wave having a wavelength from about 200 nm to about 1200 nm. Alternatively, the laser beam may be a pulse wave.

When the second source gas and the modified layer 510 chemically react with one another, the higher the temperature is, the higher the reactivity may be. When the modified layer 510 that reacted with the second source gas is evaporated and removed at a high temperature (about 400° C. or higher), the reactivity is good, and thus, the process speed may be fast. Operation (d) (operation S14) is a pre-processing process for the efficient removal of the modified layer 510, and the substrate 500 and the modified layer 510 may be heated to the second temperature. The second temperature may be from about 250° C. to about 400° C.

The laser beam supply 400 according to aspects of the inventive concept is a non-contact heater and may facilitate rapid change of the temperature of the substrate 500. For example, by appropriately setting the temperature in an operation of removing the modified layer 510, the modified layer 510 may be removed efficiently.

FIG. 8E shows operation (e) (operation S15) of removing the modified layer 510 by spraying the second source gas 320 from the shower head 103 toward the substrate 500.

Referring to FIG. 8E, the second source gas 320 sprayed from the shower head 103 may chemically react with the modified layer 510 on the first surface 500F of the substrate 500. The modified layer 510 that reacted with the second source gas 320 may be evaporated and removed from the substrate 500.

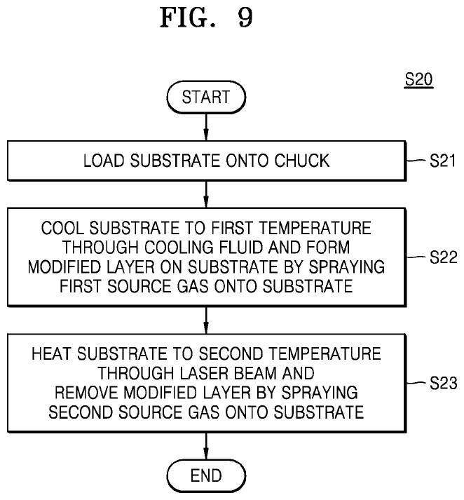

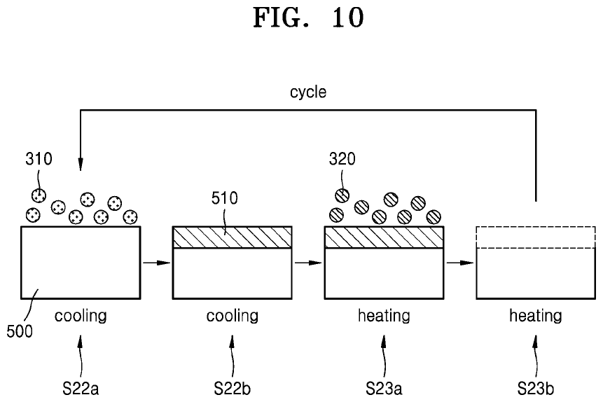

FIG. 9 is a flowchart of an ALE method according to an embodiment. FIG. 10 is a schematic cross-sectional view of each operation of an ALE method according to an embodiment.

Referring to FIG. 9, in an ALE method S20, operation (a) of loading a substrate onto a chuck may be performed (operation S21). After operation (a), operation (b) of cooling the substrate to a first temperature through a cooling fluid and spraying a first source gas on the substrate to form a modified layer on the substrate may be performed (operation S22). After operation (b), operation (c) of heating the substrate to a second temperature through a laser beam and spraying a second source gas on the substrate to remove the modified layer may be performed (operation S23).

According to some embodiments, operations (a), (b), and (c) may be repeated until a target film reaches a set thickness.

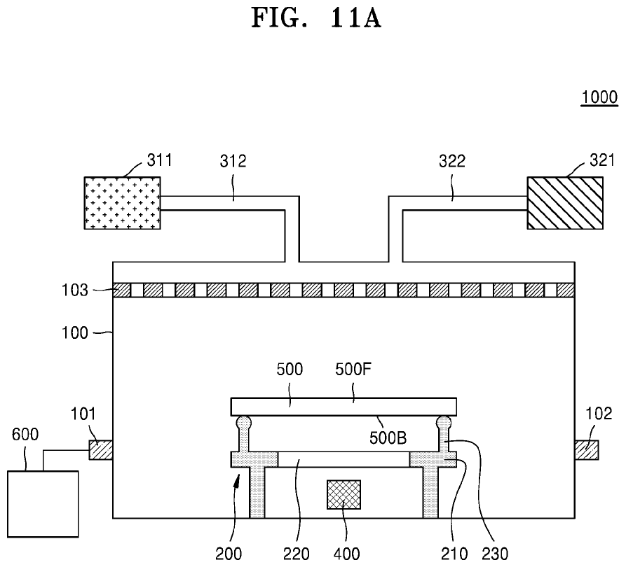

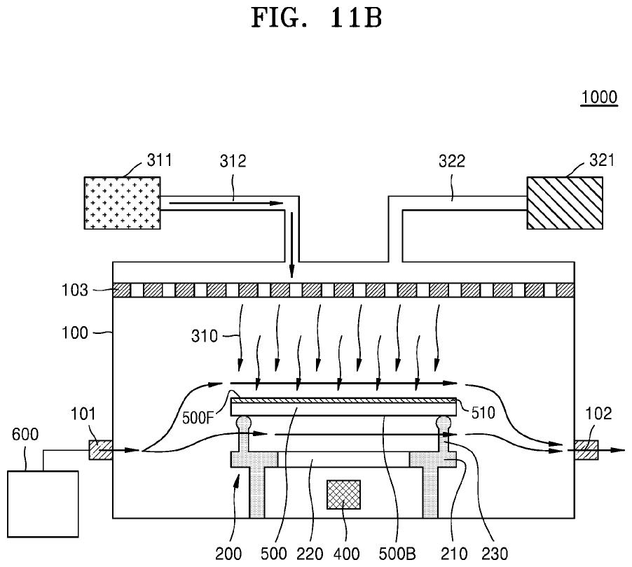

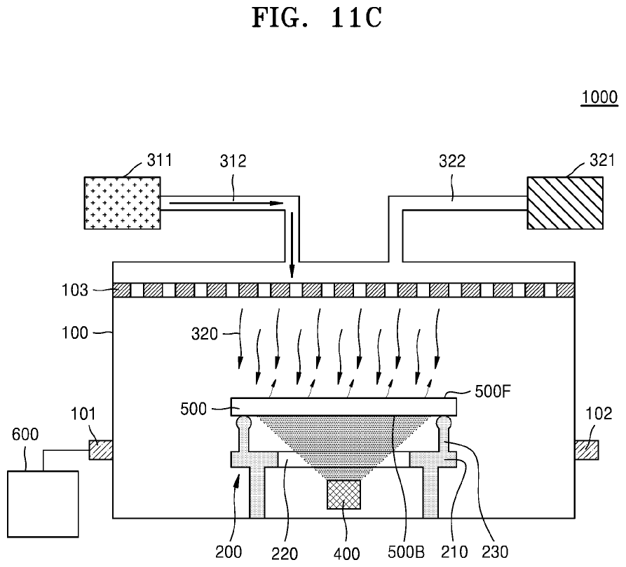

Referring to FIG. 10, the process sequence of the ALE method of FIG. 9 is shown by focusing on changes of the substrate 500. The first source gas 310 may be sprayed onto the first surface of the substrate 500 while maintaining the substrate 500 at the first temperature through the cooling fluid (operation S22a). At the first temperature, the first source gas 310 may react with the target film of the substrate 500 and form a modified layer 510 (operation S22b). The second source gas 320 may be sprayed onto the first surface of the substrate 500 while maintaining the substrate 500 and the modified layer 510 at the second temperature through the laser beam supply (operation S23a). At the second temperature, as the second source gas 320 and the modified layer 510 react with each other, the modified layer 510 may be removed (operation S23b). Thereafter, the above-stated operations may be repeated until the target film reaches the set thickness. More detailed descriptions thereof will be given below with reference to FIGS. 11A to 11C.

FIGS. 11A to 11C are cross-sectional views sequentially showing an ALE method according to an embodiment. Hereinafter, descriptions of the ALE method of FIGS. 11A to 11C that are identical to those of the ALE method given above with reference to FIGS. 6A to 6E will be omitted, and differences therebetween will be mainly described.

FIG. 11A shows operation (a) (operation S21) in which a substrate is loaded onto a chuck. Referring to FIG. 11A, the substrate 500 may include the first surface 500F and the second surface 500B that face each other.

According to some embodiments, the chuck 200 may include the circular ring 210 and the transparent window 220. The circular ring 210 of the chuck 200 may include the plurality of grips 230 protruding upward. The substrate 500 may be loaded on the plurality of grips 230 of the chuck 200.

According to some embodiments, the transparent window 220 of the chuck 200 may be located in the center hole of the circular ring 210. The material constituting the transparent window 220 may include quartz or a material having high light transmittance. According to some embodiments, a wavelength at which the transparent window 220 is heated by a laser beam may be different from a wavelength at which the substrate 500 is heated by a laser beam.

FIG. 11B shows operation (b) (operation S22) of forming the modified layer 510 on the substrate 500 through a reaction between the first source gas 310 and the substrate 500 by spraying the first source gas 310 toward the substrate 500 through the shower head 103 while the substrate 500 is being cooled to the first temperature through a cooling fluid.

Referring to FIG. 11B, the cooling fluid supply 600 may be connected to the cooling fluid inlet 101 disposed on a side of the process chamber 100. The cooling fluid supply 600 may introduce the cooling fluid into the processing space in the process chamber 100 through the cooling fluid inlet 101. The cooling fluid introduced through the cooling fluid inlet 101 may flow over a first surface 500F and a second surface 500B of the substrate 500 and may be discharged to the outside through the cooling fluid outlet 102.

The first source gas supply 311 may be connected to the first source gas supply pipe 312. The first source gas supply pipe 312 may be connected to the upper portion of the process chamber 100. The first source gas supply 311 may supply the first source gas 310 to the processing space inside the process chamber 100 through the first source gas supply pipe 312. The first source gas 310 supplied to the upper portion of the processing space may be sprayed onto the first surface 500F of the substrate 500 through the shower head 103.

When the temperature of the substrate 500 is about 100° C. or lower, the reaction between the first source gas and the target film of the substrate 500 becomes active, and thus a thicker modified layer may be formed. According to some embodiments, the first temperature may be from about 50° C. to about 90° C.

FIG. 11C shows operation (c) (operation S23) of removing the modified layer 510 through a reaction between the second source gas 320 and the modified layer 510 by spraying the second source gas 320 toward the modified layer 510 through the shower head 103 while the substrate 500 is being heated to the second temperature through a laser beam.

Referring to FIG. 11C, the laser beam supply 400 capable of supplying a laser beam may be located below the transparent window 220. A laser beam supplied by the laser beam supply 400 may pass through the transparent window 220 and be irradiated onto the second surface 500B of the substrate 500. The laser beam may be refracted by the refractive index of the transparent window 220 while passing through the transparent window 220. The laser beam may be irradiated onto the entire or a part of the second surface 500B of the substrate 500. According to some embodiments, the second temperature may be from about 250° C. to about 400° C. According to some embodiments, the laser beam may be a continuous wave having a wavelength from about 200 nm to about 1200 nm.

The second source gas supply 321 may be connected to the second source gas supply pipe 322. The second source gas supply pipe 322 may be connected to the upper portion of the process chamber 100. The second source gas supply 321 may supply the second source gas 320 to the processing space in the process chamber 100 through the second source gas supply pipe 322. The second source gas 320 supplied to the upper portion of the processing space may be sprayed onto the first surface 500F of the substrate 500 through the shower head 103.

A chemical reaction between the second source gas 320 and the modified layer 510 may exhibit increased reactivity at a high temperature. According to aspects of the inventive concept, the temperature of the substrate 500 and the modified layer 510 may be rapidly increased or maintained through the laser beam supply 400. An operation of removing the modified layer 510 may be performed at a high temperature, and thus the modified layer 510 may be effectively removed.

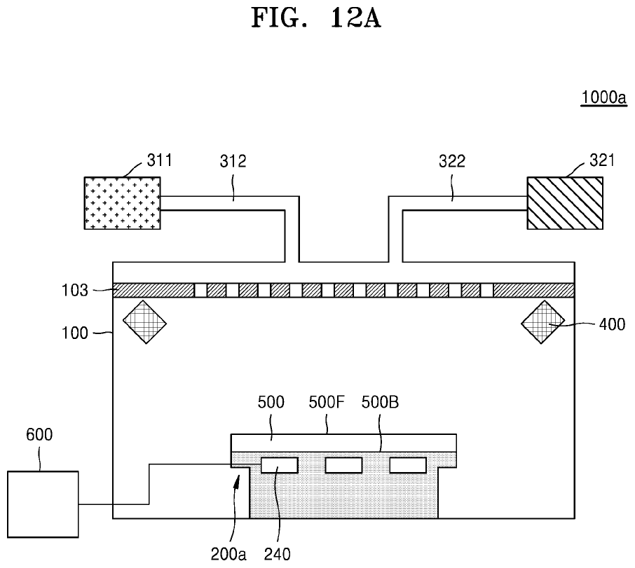

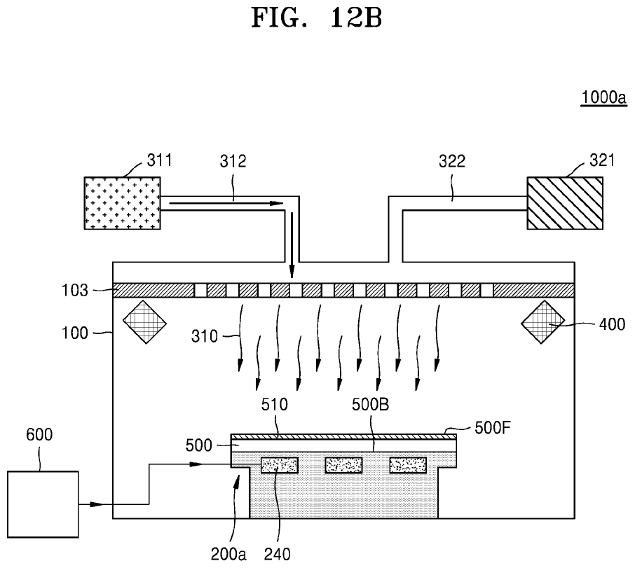

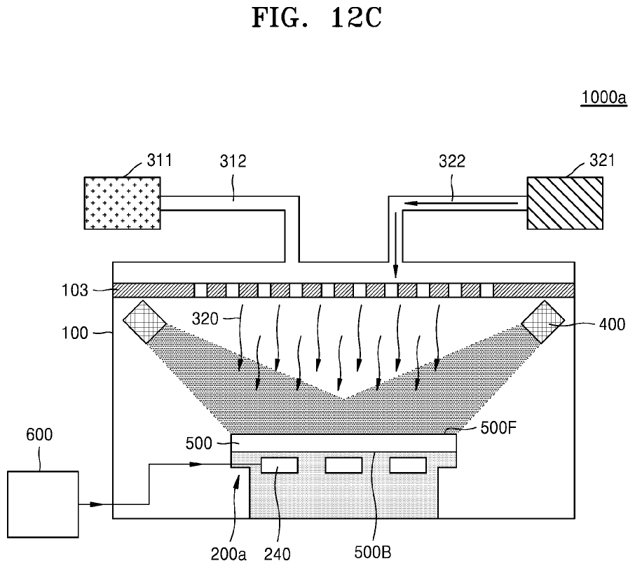

FIGS. 12A to 12C are cross-sectional views sequentially showing an ALE method according to an embodiment.

Hereinafter, descriptions of the ALE method of FIGS. 12A to 12C that are identical to those of the ALE method given above with reference to FIGS. 11A to 11C will be omitted, and differences therebetween will be mainly described.

FIG. 12A shows operation (a) (operation S21) in which a substrate is loaded onto a chuck.

Referring to FIG. 12A, the substrate 500 may include the first surface 500F and the second surface 500B that face each other. According to some embodiments, the chuck 200a of the ALE apparatus 1000a may be an electrostatic chuck. The electrostatic chuck may be configured to support the substrate 500 with an electrostatic force. According to some embodiments, the chuck 200a of the ALE apparatus 1000a may be a vacuum chuck. The vacuum chuck may be configured to selectively vacuum-adsorb the substrate 500. The second surface 500B of the substrate 500 loaded on the chuck 200a may entirely contact the chuck 200a. For example, the substrate 500 loaded on the chuck 200a may not be spaced apart from the chuck 200a.

FIG. 12B shows operation (b) (operation S22) of forming the modified layer 510 on the substrate 500 through a reaction between the first source gas 310 and the substrate 500 by spraying the first source gas 310 toward the substrate 500 through the shower head 103 while the substrate 500 is being cooled to the first temperature through a cooling fluid.

Referring to FIG. 12B, the chuck 200a may include the cooling fluid flow pipe 240 therein. The cooling fluid flow pipe 240 may be connected to the cooling fluid supply 600. The cooling fluid supply 600 may supply a cooling fluid to the inside of the chuck 200a through the cooling fluid flow pipe 240. The cooling fluid supplied into the chuck 200a may cool the substrate 500 loaded on the chuck 200a to the first temperature.

When the temperature of the substrate 500 is about 100° C. or lower, the reaction between the first source gas and the target film of the substrate 500 becomes active, and thus a thicker modified layer may be formed. According to some embodiments, the first temperature may be from about 50° C. to about 90° C.

FIG. 12C shows operation (c) (operation S23) of removing the modified layer 510 through a reaction between the second source gas 320 and the modified layer 510 by spraying the second source gas 320 toward the modified layer 510 through the shower head 103 while the substrate 500 is being heated to the second temperature through a laser beam.

Referring to FIG. 12C, the laser beam supply 400 for supplying a laser beam may be located above the substrate 500. The laser beam supply 400 may be configured to irradiate a laser beam onto the first surface 500F of the substrate 500. According to some embodiments, the ALE apparatus 1000a may include a plurality of laser beam supplies 400 each supplying a laser beam. A laser beam supplied from each laser beam supply 400 may irradiate the entire or a part of the first surface 500F of the substrate 500. The laser beam may be a continuous wave having a wavelength absorbable by the substrate 500. For example, the laser beam may be a continuous wave having a wavelength from about 200 nm to about 1200 nm. Alternatively, the laser beam may be a pulse wave.

A chemical reaction between the second source gas 320 and the modified layer 510 may exhibit increased reactivity at a high temperature. According to aspects of the inventive concept, the temperature of the substrate 500 and the modified layer 510 may be rapidly increased or maintained through the laser beam supply 400. An operation of removing the modified layer 510 may be performed at a high temperature, and thus the modified layer 510 may be effectively removed.

While aspects of the inventive concept have been particularly shown and described with reference to embodiments thereof, it will be understood that various changes in form and details may be made therein without departing from the spirit and scope of the following claims.

What is claimed is:

1. An atomic layer etching (ALE) method comprising:
operation (a) of loading a substrate having a first surface and a second surface facing each other onto a chuck;
operation (b) of cooling the substrate to a first temperature through a cooling fluid;
operation (c) of forming a modified layer on the substrate through a reaction between a first source gas and the first surface of the substrate by spraying the first source gas toward the substrate from a shower head positioned above the chuck;
operation (d) of heating the substrate to a second temperature through a laser beam; and
operation (e) of removing the modified layer of the substrate through a reaction between a second source gas and the modified layer of the substrate by spraying the second source gas from the shower head toward the first surface of the substrate.

2. The ALE method of claim 1, wherein the chuck comprises a circular ring and a transparent window disposed in a center hole of the circular ring,
the circular ring comprises a plurality of grips protruding upward, and,
in the operation (a), the substrate is supported on the plurality of grips of the chuck and spaced apart from the transparent window.

3. The ALE method of claim 2, wherein, in the operation (b), the cooling fluid flows in from a side of the substrate and flows above and below the substrate.

4. The ALE method of claim 2, wherein a laser beam supply for supplying a laser beam is positioned below the transparent window, and,
in the operation (d), the laser beam passes through the transparent window and is irradiated onto the second surface of the substrate to thereby heat the substrate.

5. The ALE method of claim 4, wherein a lens is disposed between the laser beam supply and the transparent window, and the laser beam passes through the lens and the transparent window in turn and heats the substrate.

6. The ALE method of claim 1, wherein operations (b), (c), (d), and (e) are repeated until a target film of the substrate reaches a set thickness.

7. The ALE method of claim 6, wherein the target film comprises a metal oxide film, a metal nitride film, or a high dielectric film,
in the operation (c), the first source gas comprises HF, SF₄ or XeF₄, and,
in the operation (e), the second source gas comprises trimethylaluminum, Sn(acac)₂, Al(CH₃)₃, Al(CH₃)₂Cl, SiCl₄, TiCl₄, BCl₃, or WF₆.

8. The ALE method of claim 1, wherein the laser beam comprises a continuous wave having a wavelength from about 200 nm to about 1200 nm.

9. The ALE method of claim 1, wherein the first temperature is from about 50° C. to about 90° C., and
the second temperature is from about 250° C. to about 400° C.

10. The ALE method of claim 1, wherein the chuck comprises a cooling fluid flow pipe therein, and,
in the operation (a), the second surface of the substrate is in contact with the chuck.

11. The ALE method of claim 10, wherein, in the operation (b), the cooling fluid flows in the cooling fluid flow pipe of the chuck to cool the substrate.

12. The ALE method of claim 1, wherein a laser beam supply for supplying the laser beam is positioned above the substrate, and,
in the operation (d), the laser beam is irradiated onto the first surface of the substrate to heat the substrate.

13. The ALE method of claim 12, wherein, in the operation (d), the substrate is heated through a plurality of laser beam supplies each supplying a laser beam.

14. An atomic layer etching (ALE) method comprising:
operation (a) of loading a substrate having a first surface and a second surface facing each other onto a chuck;
operation (b) of forming a modified layer on the substrate through a reaction between a first source gas and the first surface by spraying the first source gas toward the substrate from a shower head positioned above the chuck while the substrate is being cooled to a first temperature through a cooling fluid; and
operation (c) of removing the modified layer of the substrate through a reaction between a second source gas and the modified layer of the substrate by spraying the second source gas toward the modified layer of the substrate from the shower head while the substrate is being heated to a second temperature through a laser beam.

15. The ALE method of claim 14, wherein operations (b) and (c) are repeated until a target film of the substrate reaches a set thickness,
the target film comprises a metal oxide film, a metal nitride film, or a high dielectric film,
in the operation (b), the first source gas comprises HF, SF₄ or XeF₄, and,
in the operation (c), the second source gas comprises trimethylaluminum, Sn(acac)₂, Al(CH₃)₃, Al(CH₃)₂Cl, SiCl₄, TiCl₄, BCl₃, or WF₆.

16. The ALE method of claim 14, wherein the first temperature is from about 50° C. to about 90° C., and
the second temperature is from about 250° C. to about 400° C.

17. The ALE method of claim 14, wherein the laser beam comprises a continuous wave having a wavelength from about 200 nm to about 1200 nm.

18. An atomic layer etching (ALE) apparatus comprising:
a process chamber;
a chuck configured to support a substrate having a first surface and a second surface facing each other;
a shower head positioned above the substrate;
a first source gas supply configured to supply a first source gas to the shower head;
a second source gas supply configured to supply a second source gas to the shower head;
a laser beam supply configured to irradiate a laser beam onto the substrate; and
a cooling fluid supply configured to supply a cooling fluid into the process chamber.

19. The ALE apparatus of claim 18, wherein the process chamber comprises a cooling fluid inlet and a cooling fluid outlet,
the cooling fluid supply is connected to the cooling fluid inlet,
the chuck comprises a circular ring and a transparent window disposed in a center hole of the circular ring,
the circular ring comprises a plurality of grips protruding upward and configured to support the substrate, and
the laser beam supply is positioned below the transparent window and configured to irradiate a laser beam toward the second surface of the substrate through the transparent window.

20. The ALE apparatus of claim 18, wherein the chuck comprises a cooling fluid flow pipe therein,
the cooling fluid supply is connected to the cooling fluid flow pipe, and
the laser beam supply is located above the substrate and configured to irradiate a laser beam toward the first surface of the substrate.
